(19) United States
(12) Patent Application Publication
(10) Pub. No.: US 2005/0277237 A1
(43) Pub. Date: Dec. 15, 2005

(54) Structure from which an integrated circuit may be fabricated and a method of making same

(76) Inventors: Mei-Yun Wang, Hsin-Chu (TW); Chih-Wei Chang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/867,078

(22) Filed: Jun. 14, 2004

(51) Int. Cl. H01L 21/336; H01L 21/8238; H01L 21/8234

(52) U.S. Cl. 438/197

(57) ABSTRACT

Deep silicidation of a polysilicon gate electrode following high temperature annealing of a source/drain under the gate may damage the gate oxide. This damage is prevented by forming the gate electrode as two polysilicon layers separated by a chemical oxide. During annealing the chemical oxide prevents the grains of one polysilicon layer from merging with the grains of the other polysilicon layer. Thereafter, silicidation is substantially confined to the top polysilicon layer, the low resistance of which shunts the bottom polysilicon layer through the chemical oxide.

### TECHNICAL FIELD

The present invention relates to a structure from which an integrated circuit may be fabricated and a method of making such a structure. More particularly, the present invention relates to a structure from which a transistor, such as a MOSFET, may be fabricated and wherein deposited materials from which a gate electrode and associated interconnects are formed may be silicided without deleteriously affecting the gate dielectric. The present invention also contemplates a method of making such a structure.

### BACKGROUND

Integrated circuits are interconnected networks of electrical components fabricated on a common substrate. Various conventional techniques, such as layering, doping, masking, and etching, are used to form myriad microscopic components, including resistors, transistors, capacitors and other electrical components on a silicon substrate. The components are then electrically interconnected to define one or more electrical circuits, such as a memory or a microprocessor.

Many integrated circuits include a type of transistor known as a metal-oxide-semiconductor field-effect transistor, or “MOSFET.” A MOSFET has four major elements, specifically, a substrate, a source, a drain, and a gate. A channel is defined in the substrate between the source and the drain, and the gate overlies the channel. The MOSFET and its elements are electrically interconnected to other MOSFETs and their elements and to other components fabricated in and on the substrate to form an electrical integrated circuit.

A MOSFET functions primarily as a switch, its gate opening and closing the channel in the substrate between its source and drain. The channel is selectively rendered conductive (opened) or nonconductive (closed) by the application of appropriate electrical signals to the gate.

The gate of a MOSFET is typically two-layered. The two-layered gate has a top electrically conductive layer, or gate electrode, that is separated from the underlying channel in the substrate by a subjacent insulative, dielectric layer, or gate dielectric. The gate electrode had, in the past, been formed from a metal-containing material, but the metal tended to diffuse through the gate dielectric compromising the insulative/dielectric properties thereof and permitting undesirable electrical conduction between the gate electrode and the underlying channel. Moreover, if the metal gate electrode did not possess a sufficiently high melting temperature, certain high-temperature processing steps, such as the annealing typically involved in forming the source and the drain, could damage or destroy it. Present MOSFET designs usually utilize gate electrodes comprising electrically conductive polycrystalline silicon (i.e., “polysilicon” or “poly”), which causes no adverse diffusion and has a high melting temperature.

The electrical interconnections between the gate electrode of a MOSFET and other elements of an integrated circuit are also presently typically made from electrically conductive polysilicon. A gate electrode and its associated interconnections may constitute a layer of polysilicon that is patterned into “lines.”

Polysilicon typically has a multi-crystalline structure instead of the single-crystalline structure of the silicon substrate; long-range order is maintained only within limited grains. Polysilicon is electrically conductive, but has a very high electrical resistance. Polysilicon can be doped to act as a better conductor, but its electrical resistance remains high, typically ten or more times the electrical resistance of a metal. The high electrical resistance of polysilicon is presently ameliorated by silicidation, a process of reacting polysilicon with a metal, typically nickel, tungsten, tantalum, cobalt or titanium. Other metals used in siliciding polysilicon include chromium, molybdenum, gold, palladium and zirconium.

In a typical MOSFET transistor fabrication sequence, conductive lines are formed by a self-aligned siliciding technique, called “saliciding” (from “Self ALIgned siliCIDE”). Specifically, a dielectric layer is first deposited on the substrate. At the locations where the channels of each incipient transistor will be formed, the dielectric layer will function as the gate dielectric. Next, a polysilicon layer is deposited on the dielectric layer and is then patterned to define the lines (gate electrodes and interconnects). Ion implantation procedures that form the source and drain of each incipient MOSFET are carried out at the exposed substrate regions. Formation of the sources/drains is followed by rapid high-temperature annealing (“RTA”) in a suitable atmosphere. The patterned polysilicon is then silicided by its exposure to and reaction with a selected metal, thereby producing the highly conductive lines that constitute the gate electrodes and interconnections.

It has been found that, when the foregoing fabrication sequence is followed, the gate oxide may be damaged and its integrity compromised, leading to the possibility of leakage current between the gate electrode and the channel and the concomitant failure of the MOSFET transistors. It is theorized that such gate oxide damage is caused by the multi-grained structure of the patterned polysilicon being transformed to a single grained structure during the annealing (“RTA”) procedures that follow source/drain formation by ion implantation. Thereafter, siliciding the patterned, single-grained polysilicon effects reaction of the metal and the polysilicon deep in the patterned polysilicon causing the oxide damage.

Specifically, scaling (decreasing the physical size of) MOSFETs involves forming narrower polysilicon lines. Since it is known that the thickness of a silicided line is correlated to the width of the original polysilicon line, siliciding a narrower polysilicon line results in a thicker silicided line if the silicide is metal diffusion dominated. Scaling has resulted in efforts to produce lines less than 50 nm wide. Apparently, during RTA, the grains of a thinner polysilicon line merge into one large, deeply extending grain. The subsequent silicidation of the line produces a large, deeply extending silicide grain in contact with and impinging on the gate dielectric layer. This contact may physically damage and/or otherwise compromise the insulative properties of the dielectric, leading to ultimate MOSFET failure.

### SUMMARY OF THE INVENTION

The present invention contemplates eliminating the above-described gate oxide damage. Specifically, the present invention comprises a method of making a structure from which a transistor may be fabricated, in which damage to the gate oxide layer resulting from silicidation of a polysilicon line is avoided. The present invention also comprises the structure produced by such method.

In one aspect, the present invention provides for a structure from which a MOSFET may be fabricated. The structure comprises a substrate-supported gate oxide layer, an unsilicided polysilicon layer on the gate oxide layer, a chemical oxide layer on the first polysilicon layer, and a silicided polysilicon layer on the chemical oxide layer.

In another aspect, the present invention provides for a structure from which a MOSFET may be fabricated. The structure comprises a substrate-supported gate oxide layer that is patterned to define a gate oxide, and an incipient gate electrode that is patterned to congruently overlie the gate oxide. The incipient gate electrode includes an unsilicided polysilicon layer on the gate oxide layer, a chemical oxide layer on the first polysilicon layer, and a silicided polysilicon layer on the chemical oxide layer.

In yet another aspect, the present invention provides for a structure from which a MOSFET may be fabricated. The structure comprises a substrate-supported gate oxide layer patterned to define a gate oxide that overlies a channel in the substrate defined between a source and a drain, wherein, during the formation of the source and the drain, the structure is subjected to high temperature, and a gate electrode that is patterned to congruently overlie the gate oxide. The gate electrode includes a silicided polysilicon layer on the gate oxide layer, a chemical oxide layer on the first polysilicon layer, and a partially silicided polysilicon layer on the chemical oxide layer. Both polysilicon layers are unsilicided at the time the structure is subjected to the high temperature. The high temperature effects merger of grains of the polysilicon layers. The chemical oxide layer prevents merger of the grains of each polysilicon layer with the grains of the other polysilicon layer so that the grain organizations of each polysilicon layer are separate. Silicidation is effected after source and drain formation, and the chemical oxide layer and the separate grain organizations substantially minimize silicidation of the lower polysilicon layer.

In another aspect, the present invention provides for a method of forming a highly conductive line. The method comprises depositing a first polysilicon layer on a surface, forming a thin chemical oxide layer on a free surface of the first polysilicon layer, depositing a second polysilicon layer on the chemical oxide layer, heating the layers to effect merger of polysilicon grains of the first and second polysilicon layers, the chemical oxide layer preventing merger of the grains of one layer with the grains of the other layer so that the grain organizations of each polysilicon layer are separate, and placing the layers in a siliciding environment. The chemical oxide layer and the separate grain organizations substantially confine silicidation to the second polysilicon layer and substantially prevent silicidation of the first polysilicon layer, the polysilicon layers being electrically continuous through the chemical oxide layer.

In yet another aspect, the present invention provides for a method of making a structure from which a MOSFET may be fabricated. The method comprises forming a gate oxide on a semiconductor substrate, forming a first polysilicon layer on the gate oxide, forming a chemical oxide layer on the first polysilicon layer, forming a second polysilicon layer on the chemical oxide layer, patterning the polysilicon layers and the chemical oxide layer to form a line, a portion of which overlies the gate oxide, and forming a source and a drain in the substrate to define therebetween a channel subjacent to the gate oxide. The formation of the source and drain includes subjecting the patterned polysilicon layers to a temperature sufficiently high to effect merger of polysilicon grains. The chemical oxide layer prevents the grains of one polysilicon layer from merging with the grains of the other polysilicon layer so that the polysilicon grains merge into separate grain organizations. The layers are then placed in a siliciding environment, the chemical oxide layer and the separate grain organizations effecting silicidation of the second polysilicon layer while the first polysilicon layer remains substantially unsilicided. The polysilicon layers are electrically continuous through the chemical oxide layer, and the patterned polysilicon layers overlying the gate oxide function as a gate electrode.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a generalized depiction of a prior art structure from which a MOSFET may be fabricated;

FIG. 2 is a generalized depiction illustrating a structure fabricated according to the principles of the present invention from which a structure representing an improvement over that shown in FIG. 1 may be produced; and

FIGS. 3a and 3b are generalized depictions illustrating alternative improved structures fabricated from the structure of FIG. 2 according to the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

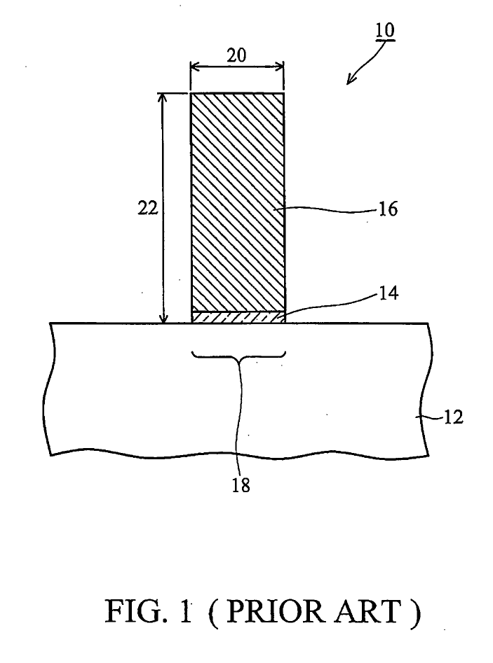

Referring first to FIG. 1, a prior art structure 10 from which a MOSFET may be fabricated is shown. The structure 10 includes a semiconductor substrate 12, typically silicon, on which there is an oxide layer 14 serving as a gate dielectric. A gate electrode 16 is vertically aligned with and congruently overlies and resides on the gate dielectric 14. The gate electrode 16 is typically a segment of an extended, narrow conductive line that extends into and out of the plane of FIG. 1. Portions of the line that congruently overlie neighboring gate dielectric regions also constitute gate electrodes thereat. Portions of the line that do not overlie gate dielectric regions constitute interconnects.

The gate dielectric 14 results from selectively patterning an area oxide layer (not shown), typically SiO₂, formed on the surface of the substrate 12. The gate electrode 16 results from selectively patterning a high electrical resistivity polysilicon area layer (not shown) formed on the gate dielectric, and then reducing the electrical resistivity of the polysilicon by siliciding it. Siliciding is effected by reacting the polysilicon with a metal such as nickel, tungsten, tantalum, cobalt, titanium, or other metals noted above.

After patterning the area oxide and polysilicon layers, but before siliciding the polysilicon, a source (not shown) and a drain (not shown) are formed in the substrate 12 to define therebetween a channel, generally located at 18. Typically, the source/drain are formed by ion implantation, following which the structure 10 is subjected to RTA, that is, rapid high-temperature annealing.

As discussed earlier, it has been found that if the polysilicon gate electrode 16 is narrow, having, for example, a width 20 of about 10 to about 50 nm (with a height 22 of about 60-150 nm or more), RTA may cause the multi-grain structure of the gate electrode 16 to become, or merge into, a single, large grain abutting the gate oxide 14. Should this occur, when, following annealing, the polysilicon of the electrode 16 is silicided, this single large polysilicon grain will become a larger silicide grain adjacent to and contacting the gate oxide 14. It is postulated that the adjacent silicide grain may damage the gate oxide 14 due to spiking or other phenomena, compromising the dielectric/insulative properties and causing the ultimate failure thereof.

The present invention eliminates this damage to the gate dielectric 14 by: (1) preventing the polysilicon of the gate electrode 16 from merging into a single large grain following RTA, and (2) preventing silicidation of the grain or grains of the polysilicon of the electrode 16 adjacent to the gate oxide 14, while permitting silicidation of the grain or grains of polysilicon of the electrode 16 remote from the gate oxide 14. The foregoing is achieved in a manner that permits effective and efficient silicidation of the remote portion of the polysilicon of the electrode 16—in shunt with the higher resistivity gate-adjacent polysilicon portion—to lower the electrical resistance of the electrode 16 to a desirable level.

It should be noted that, with regard to the following discussion, although the term “siliciding” and its derivatives are used, the preferred, but non-exclusive, mode of forming silicides is by salicidation, that is, a self-aligned area silicidation process. Also, the dimension 20 of the gate electrode is referred to herein as its “width,” although, strictly speaking, in a MOSFET, this dimension 20 is the length of the gate 14+16.

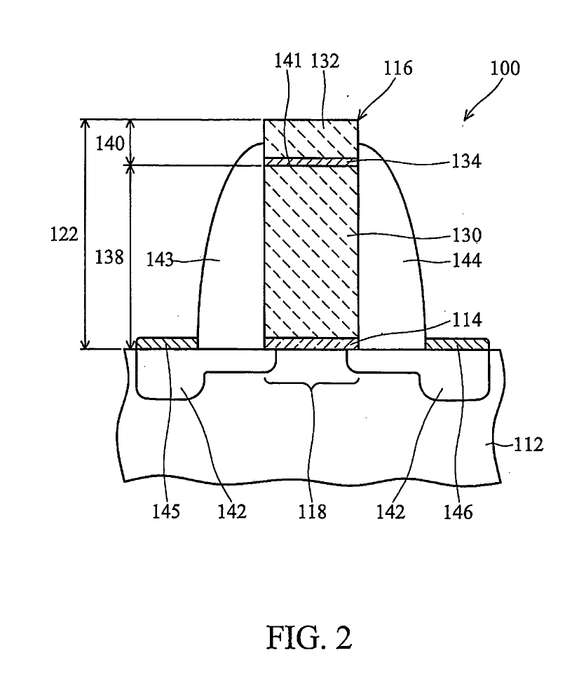

Referring now to FIG. 2, there is shown an improved structure 100 according to one aspect of the present invention as it exists prior to formation of a source/drain, RTA, and silicidation. The improved structure 100 includes a substrate 112 having thereon, in order, a gate oxide 114 and an incipient, unsilicided polysilicon gate electrode 116. The gate oxide 114 and the incipient gate electrode 116 are vertically aligned and congruent with each other and with the location 118 of a channel that will be defined between the source/drain. The manufacturing steps for forming the intermediate structure illustrated in FIG. 2 are well known in the art. Typically, gate oxide 114 is blanket deposited using, e.g., a thermal oxide process. A first polysilicon layer is then deposited, followed by a blanket deposition of a chemical oxide layer, followed by deposition of a second polysilicon layer. Deposition of these layers can be accomplished using known techniques. Next, the device is masked with a photolithography mask, and the first and second polysilicon layers, the chemical oxide layer, and the gate oxide layer is etched to form the gate electrode 116. Spacers 143 and 144 are formed, preferably by a process of depositing and anisotropically etching a dielectric layer or layers, preferably formed of silicon oxide, silicon nitride, or combinations thereof. Source and drain regions 142 are formed by ion implantation using gate electrode 116 and/or spacers 143, 144 as ion implantation masks, as is known in the art.

The incipient gate electrode 116, which has an initial or “target” height dimension 122, is divided into a lower polysilicon portion 130 adjacent the gate oxide 114 and an upper polysilicon portion 132 remote from the gate oxide 114 by a very thin (0.3-3 nm) chemical oxide barrier layer 134. The chemical oxide or barrier layer 134 is of a “poor quality,” as compared, for example, to the “good quality” gate oxide 114. Specifically, as used herein, “chemical oxide” means a hydrated silicon oxide having a composition of a mixture of stoichiometric SiO₂ and intermediate states of silicon oxide (i.e., SiOₓ, where x≦2). This chemical oxide exhibits low density, and possesses relatively poor dielectric and electrical insulating properties. The initial height 122 is selected so that the height of the electrode 116 after silicidation is approximately equal to the height 22 of the prior art electrode 16.

The lower polysilicon portion 130 of the incipient gate electrode 116 has an initial height 138 less than the target height 122. The height 138 of the lower portion 130 may range from about 30 nm to about 200 nm, but preferably has a value that results in the lower portion 130 having a height of about 40 nm to about 130 nm after silicidation. The upper polysilicon portion 132 has an initial height 140, which, when added to the height 138, results in the target height 122, having a value of between about 60 nm to about 150 nm (ignoring the small height of the chemical oxide layer 134) after silicidation. The initial height 140 may range from about 10 nm to about 30 nm.

The chemical oxide barrier layer 134 may be formed by exposing the free surface 141 of the lower polysilicon portion 130, after its conventional formation, to an acid, a base or ozone. Preferably, the chemical oxide layer 134 is formed by exposing the free surface 141 to DIO₃ (ozonated deionized water) or to a mixture of NH₄OH:H₂O₂:H₂O or HCl:H₂O₂:H₂O in a suitable ratio, e.g., 1:1:5, 1:2:6, or 1:1:50, that is similar to the so-called SC1 and SC2 formulae. After the chemical oxide layer 134 is formed, the upper portion 132 of the incipient gate electrode 116 is conventionally formed thereon.

Conveniently, the structure 100 of FIG. 2 may result from forming an area gate oxide layer (not shown) on the substrate 112, forming a first area polysilicon layer (not shown) on the gate oxide layer, forming a chemical oxide area layer (not shown) on the first area polysilicon layer, and then forming a second area polysilicon layer (not shown) on the chemical oxide area layer. The structure 100 results from performing selective patterning of the various layers. It has been found that the chemical oxide layer 134 has little or no impact on the patterning of the polysilicon layers.

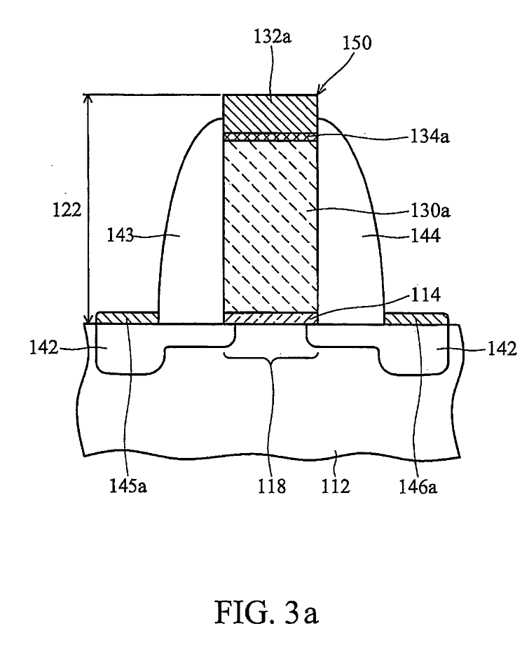

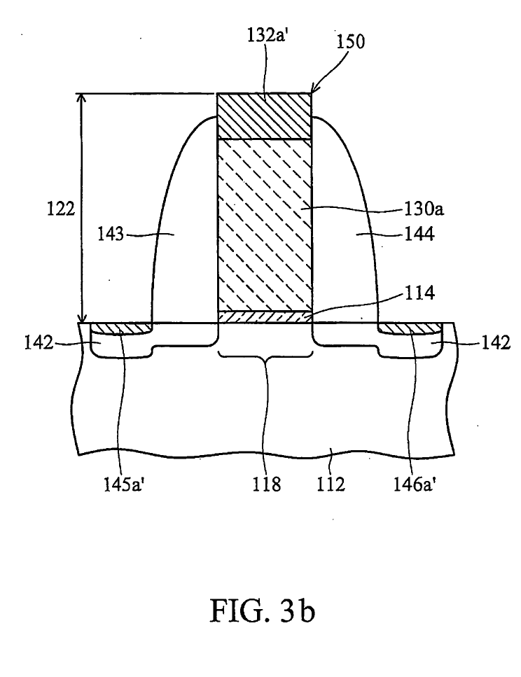

After the structure 100, including the incipient gate electrode 116, has been formed, ion implantation protocols are followed to form the source/drain 142/142 under the incipient gate 114+116, thereby defining the channel 118. The structure 100 is now an incipient transistor. Spacers 143 and 144 are formed in a conventional manner to cover the sides of the incipient gate 114+116 and selected areas of the substrate 112 that include the source/drain 142/142. Polysilicon layers 145 and 146 may be formed over areas of the source/drain 142/142 not covered by the spacers 143 and 144, although a preferred alternative is depicted and described with reference to FIG. 3b.

As discussed above, ion implantation protocols include rapid high-temperature annealing (RTA) procedures following ion implantation of the source/drain 142/142. RTA effects organization of the grains of the polysilicon of the upper and lower portions 130 and 132 of the incipient gate electrode 116 and the polysilicon layers 145 and 146 (where present) into one large grain or several large grains. However, the poor quality chemical oxide 134 has been found to prevent the organization of the incipient gate electrode 116 into an integrated grain structure made up of one large grain or several large grains, as is the case with the prior art gate electrode 16. Rather, following RTA, the incipient electrode 116 has two, separate and distinct, and/or differently oriented, grain structures, one grain structure being in the upper portion 132 and another, separate grain structure being present in the lower portion 130.

Whether either portion 130,132 evolves into a single- or multi-grained structure, the grain structures of each are disassociated and separate due to the presence of the oxide barrier layer 134. That is, the oxide barrier layer 134 prevents the grains of one layer 130,132 from merging with the grains of the other layer 132,130, so that the grain organizations of each polysilicon layer are separate. The separate grain structures and organizations may each comprise multiple grains or a single grain. However, even if both portions 130,132 both comprise a single large grain, their orientations are not the same.

Referring now to FIG. 3a, the incipient gate electrode 116 and the polysilicon layers 145 and 146 of FIG. 2 (where present) have been subjected to silicidation by reacting them with a selected metal, thus producing a gate electrode 150 and source/drain contacts 145a and 146a. It has been found that, following silicidation, the presence of the poor quality oxide 134 and the resulting separate and differently oriented grain organizations of the upper and lower portions 132,130 result in high silicidation of the upper portion 132, now identified as 132a, and low (or no) silicidation of the lower portion 130, now identified as 130a. The oxide 134 may partially or completely merge into the upper portion 132a during silicidation, as indicated at 134a.

In the embodiment illustrated in FIG. 3a, the upper polysilicon portion 132 and the oxide barrier layer 134 are shown as remaining distinct even after the silicidation process. While vestiges of the oxide barrier layer 134 may remain after silicidation and other processing, it is more likely that the upper oxide layer 132 and the polysilicon layer 134 will completely or nearly completely merge during silicidation and other processing, resulting in the structure shown in FIG. 3b. Note that FIG. 3b illustrates a lower polysilicon portion 130a and an upper polysilicon portion 132a′ indicating that the barrier layer 134 has effectively merged into and become indistinct from the upper portion 132a′. Those skilled in the art will recognize that, under certain circumstances, the oxide barrier layer 134 may fully or partially merge into the lower polysilicon portion 130a, as well as, or in addition to, merging into the upper polysilicon portion 132a.

As shown in FIG. 3b, the source/drain contacts 145a/146a are, in preferred embodiments, not formed from the deposited polysilicon layers 145 and 146. Rather, the source/drain contacts 145a/146a are preferably formed by directly siliciding the regions of the substrate 112 in which the source/drain 142/142 have been ion implanted. That is, it is preferred that the source/drain contacts 145a/146a are formed in the substrate 112, as shown in FIG. 3b, rather than above the surface of the substrate 112, as shown in FIG. 3a.

Due to the poor electrical insulative/dielectric properties of the incompletely merged or unmerged chemical oxide barrier layer 134, following silicidation the portions 130a and 132a (or 132a′) are electrically continuous. Accordingly, the resulting gate electrode 150 comprises the very low resistivity silicide upper portion 132a or 132a′ that electrically shunts the higher resistance of the mostly (or all) polysilicon lower portion 130a. Silicidation is carried out so that the electrical resistance of the source/drain contacts 145a and 146a and the gate electrode 150—wherein the higher resistance lower portion 130a is electrically shunted by the lower resistance upper portion 132a or 132a′—is at or below a selected value. Indeed, if the foregoing structure and method are carried out in producing ultra narrow (≦50 nm) lines—both the gate electrodes and the interconnects, which together constitute the lines—all the lines will have the cross-section depicted in FIGS. 3a and 3b.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that function in substantially the same manner or achieve substantially the same result as the corresponding embodiments described herein may be utilized according to the present invention. Accordingly, the appended claims are intended to include within their scope such processes, machines, manufacture, compositions of matter, means, methods, or steps.

1. A structure from which a MOSFET may be fabricated, which comprises:
a substrate-supported gate dielectric layer;
a first silicon-containing layer on the gate dielectric layer;
a barrier layer on the first silicon-containing layer; and
a second silicon-containing layer on the barrier layer, the barrier layer being effective to prevent the merger of the grains in the first layer with the grains in the second layer when the layers are subjected to a temperature that is suffiently high to effect grain merger in the layers.

2. The structure of claim 1 wherein the silicon-containing layers are polysilicon and the barrier layer is a chemical oxide layer having a thickness ranging from about 0.3 nm to about 3 nm.

3. The structure of claim 2 wherein the chemical oxide layer has low density and poor electrical insulative and dielectric characteristics.

4. The structure of claim 2 wherein the chemical oxide layer is a hydrated silicon oxide that is a mixture of stoichiometric SiO₂ and intermediate states of silicon oxide SiOₓ, where x≦2.

5. The structure of claim 4 wherein the chemical oxide layer is formed by exposing a free surface of the first polysilicon layer to an acid, a base or ozone.

6. The structure of claim 4 wherein the chemical oxide layer is formed by exposing a free surface of the first polysilicon layer to ozonated distilled water, a mixture of NH₄OH:H₂O₂:H₂O, or a mixture of HCl:H₂O₂:H₂O.

7. A structure from which a MOSFET may be fabricated, which comprises:
a substrate-supported oxide layer that is patterned to define a gate dielectric; and
an incipient gate electrode that is patterned to congruently overlie the gate dielectric, the incipient gate electrode including
a first polysilicon layer on the gate oxide layer;
a chemical oxide barrier layer on the first layer; and
a second polysilicon layer on the barrier layer.

8. The structure of claim 7, wherein the barrier layer is a hydrated silicon oxide that is a mixture of stoichiometric SiO₂ and intermediate states of SiOₓ, where x≦2.

9. The structure of claim 8, wherein the chemical oxide barrier layer has a thickness ranging from about 0.3 nm to about 3 nm and has low density and poor insulative and dielectric characteristics.

10. The structure of claim 9, wherein the chemical oxide barrier layer is effective to prevent the merger of polysilicon grains in the first polysilicon layer with grains in the second polysilicon layer when the polysilicon layers are subjected to a temperature that is sufficiently high to effect grain merger in polysilicon.

11. The structure of claim 10, wherein the chemical oxide barrier layer is formed by exposing a free surface of the unsilicided polysilicon layer to an acid, a base or ozone.

12. The structure of claim 10 wherein the chemical oxide layer is formed by exposing a free surface of the unsilicided polysilicon layer to ozonated distilled water, a mixture of NH₄OH:H₂O₂:H₂O, or a mixture of HCl:H₂O₂:H₂O.

13. A method of forming a highly conductive line, which comprises:
depositing a first silicon-containing layer on a surface;
forming a thin chemical oxide layer on a free surface of the first layer;
depositing a second silicon-containing layer on the chemical oxide layer;
subjecting the layers to heating that effects merger of the grains of the first and second layers, the chemical oxide layer preventing merger of the grains of one layer with the grains of the other layer so that the grain organizations of the first and second layers are separate; and
placing the layers in a siliciding environment, the separate grain organizations substantially confining silicidation to the second layer and substantially preventing silicidation of the first layer.

14. The method of claim 13, wherein the silicon-containing layers are polysilicon.

15. The method of claim 14 wherein the line is about 50 nm wide or less.

16. The method of claim 15 wherein the chemical oxide layer ranges in thickness from about 0.3 nm to about 3 nm.

17. The method of claim 16 wherein the height of the line ranges between about 600 nm to about 1500 nm.

18. The method of claim 17 wherein the ratio of the height of the first polysilicon layer to that of the second polysilicon layer is about 5:1.

19. The method of claim 15 wherein the chemical oxide layer comprises a hydrated silicon oxide SiOₓ, where x≦2, and has a low density and poor electrical insulative and dielectric characteristics.

20. The method of claim 19 wherein the chemical oxide layer is formed by exposing the free surface of the first polysilicon layer to an acid, a base or ozone.

21. The method of claim 19 wherein the chemical oxide layer is formed by exposing the free surface of the first polysilicon layer to ozonated distilled water, a mixture of NH₄OH:H₂O₂:H₂O, or a mixture of HCl:H₂O₂:H₂O.

22. A structure from which there may be formed an ultra narrow conductive line having a width less than or equal to about 50 nm and being capable of functioning as a gate electrode and an interconnect in an integrated circuit, comprising:
an insulative layer formed on a substrate;
a first, thicker, silicon-containing layer on the insulative layer;
an intermediate barrier layer on the first silicon-containing layer; and
a second, thinner, silicon-containing layer on the intermediate layer, the intermediate layer being effective to cause separate organization of the grain structures when the silicon-containing layers are subjected to high temperatures.

23. The structure of claim 22, wherein:
the first and second silicon-containing layers comprise polysilicon; and
the intermediate barrier layer comprises a chemical oxide.

24. A method of producing a conductive line from the structure of claim 23, which comprises:
subjecting the structure to a temperature sufficiently high to effect the formation of separate grain structures in the silicon-containing layers; and
placing the structure in a siliciding environment, the separate grain structures resulting in silicidation being substantially confined to the second layer and substantially excluded from the first layer.

25. The method of claim 24, wherein the intermediate layer partially or entirely merges with one or both of the silicon-containing layers when the structure is subjected to high temperature.

26. An integrated circuit that includes a conductive line as recited in claim 25.

27. A method of forming a structure from which a highly conductive line may be fabricated, which comprises:
forming a first layer of a crystalline material the initial grains of which, when the material is thereafter subjected to a temperature within a selected range, tend to merge into one or more larger grains;
forming on the first layer a barrier layer; and
forming on the barrier layer a second layer of substantially similar crystalline material, the barrier layer being effective to prevent merger of the grains of the first layer with the grains of the second layer so that the respective grain structures of the first and second layers are separate.

28. The structure resulting from the method of claim 27.

29. A method of forming a highly conductive line from the structure of claim 28, which comprises:
heating the layers to a temperature within the selected range; and
exposing the structure to a siliciding environment, the separate grain structures of the first and second layers substantially restricting silicidation to the second layer.

30. A method of forming an integrated circuit from the structure of claim 28, the first layer residing on a substrate, which method comprises:
producing an incipient integrated circuit by forming a source/drain in the substrate so that a channel defined therebetween is beneath the first layer;
subjecting the incipient integrated circuit to rapid thermal annealing for the source/drain at a temperature within the selected range; and then
exposing the incipient integrated circuit to a siliciding environment, the separate grain structures of the first and second layers substantially restricting silicidation to the second layer.
